(19) United States
(12) Patent Application Publication
(10) Pub. No.: US 2016/0028419 A1
(43) Pub. Date: Jan. 28, 2016

(54) Systems and Methods for Rank Independent Cyclic Data Encoding

(71) Applicant: LSI Corporation, San Jose, CA (US)

(72) Inventors: Shu Li, San Jose, CA (US); Shaohua Yang, San Jose, CA (US)

(73) Assignee: LSI Corporation, San Jose, CA (US)

(21) Appl. No.: 14/338,343

(22) Filed: Jul. 22, 2014

(51) Int. Cl. H03M 13/00; G11B 20/18; G11B 20/12; H03M 13/15

(52) U.S. Cl. CPC H03M 13/616; H03M 13/15; G11B 20/1833; G11B 20/1252; G11B 2020/1289

(57) ABSTRACT

The present inventions are related to systems and methods for data processing, and more particularly to systems and methods for data encoding.

### FIELD OF THE INVENTION

The present inventions are related to systems and methods for data processing, and more particularly to systems and methods for data encoding.

### BACKGROUND

Various data transfer systems have been developed including storage systems, cellular telephone systems, and radio transmission systems. In each of the systems data is transferred from a sender to a receiver via some medium. For example, in a storage system, data is sent from a sender (i.e., a write function) to a receiver (i.e., a read function) via a storage medium. Encoding may involve vector multiplication by a quasi-cyclic matrices. However, not all scenarios allow for use of quasi-cyclic matrices, but rather involve rank deficient matrices. Typical implementations apply specific circuits for rank deficient matrices as opposed to full ran matrices. Such an approach can lead to complex, highly tailored circuitry that may not be either efficient or to handle both rank deficient and full rank encoding.

Hence, for at least the aforementioned reasons, there exists a need in the art for advanced systems and methods for data processing.

### SUMMARY

The present inventions are related to systems and methods for data processing, and more particularly to systems and methods for data encoding.

Various embodiments of the present invention provide data processing systems that include a rank independent data encoding circuit. The rank independent encoding circuit is operable to: receive a user data input; and apply a rank independent encoding algorithm to the user data input to yield an encoded output. The rank independent encoding algorithm includes multiplying an interim data set with a quasi-pseudo inverse matrix.

This summary provides only a general outline of some embodiments of the invention. The phrases “in one embodiment,” “according to one embodiment,” “in various embodiments”, “in one or more embodiments”, “in particular embodiments” and the like generally mean the particular feature, structure, or characteristic following the phrase is included in at least one embodiment of the present invention, and may be included in more than one embodiment of the present invention. Importantly, such phases do not necessarily refer to the same embodiment. Many other embodiments of the invention will become more fully apparent from the following detailed description, the appended claims and the accompanying drawings.

### BRIEF DESCRIPTION OF THE FIGURES

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 shows a storage system including rank independent encoder circuitry in accordance with various embodiments of the present invention;

FIG. 2 shows a data transmission device including a transmitter having rank independent encoder circuitry in accordance with various embodiments of the present invention;

FIG. 3 shows a solid state memory circuit including a data processing circuit having rank independent encoder circuitry in accordance with some embodiments of the present invention;

FIG. 4a shows a method for generating a quasi-pseudo inverse matrix that may be used for rank independent encoding in accordance with various embodiments of the present invention;

FIGS. 4b-4g show steps in the method of FIG. 4a;

FIG. 5a shows a processing system including a rank independent encoder circuit in accordance with some embodiments of the present invention;

FIG. 5b shows one implementation of the rank independent encoder circuit in accordance with one or more embodiments of the present invention;

FIG. 5c shows one implementation of a shift based parity calculation circuit in accordance with one or more embodiments of the present invention; and

FIG. 5d shows an example encode matrix that may be used in relation to various embodiments of the present invention.

### DETAILED DESCRIPTION OF SOME EMBODIMENTS

The present inventions are related to systems and methods for data processing, and more particularly to systems and methods for data encoding.

Various embodiments of the present invention provide data processing systems that include a rank independent data encoding circuit. The rank independent encoding circuit is operable to: receive a user data input; and apply a rank independent encoding algorithm to the user data input to yield an encoded output. The rank independent encoding algorithm includes multiplying an interim data set with a quasi-pseudo inverse matrix. In some instances of the aforementioned embodiments, the system is implemented as part of an integrated circuit. In various instances of the aforementioned embodiments, the system is implemented as part of a storage drive. In other instances, the system is implemented as part of a communication device. In some cases, the quasi-pseudo inverse matrix represents a rank deficient matrix. In other cases, the quasi-pseudo inverse matrix represents a full rank matrix.

In some instances of the aforementioned embodiments, the quasi-pseudo inverse matrix is part of an encoding matrix, and the encoding matrix further includes a first user matrix, a second user matrix, a first interim matrix, a second interim matrix. In some such instances, the interim data set is a first interim data set, and the rank independent data encoding circuit includes: a first vector multiplier circuit operable to multiply the user data input by an inverse of the first user matrix to yield a second interim data set; a second vector multiplier circuit operable to multiply the second interim data set by the first interim matrix to yield a third interim data set; a third vector multiplier circuit operable to multiply the third interim data set by the second interim matrix to yield a fourth interim data set; a fourth vector multiplier circuit operable to multiply the user data input by the second user matrix to yield a fifth interim data set; and a fifth vector multiplier circuit operable to multiply a combination of the fourth interim data set and the fifth interim data set by the quasi-pseudo inverse matrix to yield the first interim data set. In some cases, each of the first vector multiplier circuit, the second vector multiplier circuit, the third vector multiplier circuit, the fourth vector multiplier circuit, and the fifth vector multiplier circuit is a sparse circulant vector multiplier circuit.

In various cases, the rank independent data encoding circuit further includes an adder array circuit operable to add the fourth interim data set to the fifth interim data set to yield the combination of the fourth interim data set and the fifth interim data set. In some cases, the encoding matrix further includes a third interim matrix, and the rank independent data encoding circuit further includes: a sixth vector multiplier circuit operable to multiply the first interim data set by the third interim matrix to yield a sixth interim data set; and a seventh vector multiplier circuit operable to multiply a combination of the fifth interim data set and the sixth interim data set by the first user matrix to yield a seventh interim data set. In various cases, each of the sixth vector multiplier circuit and the seventh vector multiplier circuit is a sparse circulant vector multiplier circuit. In particular cases, the adder array circuit is a first adder array circuit, and the rank independent data encoding circuit further includes a second adder array circuit operable to add the fifth interim data set to the sixth interim data set to yield the combination of the fifth interim data set and the sixth interim data set. In one or more cases, the first interim data set is a first parity set, and the rank independent data encoding circuit further includes a shift based parity calculation circuit operable to calculate a second parity set based at least in part on the seventh interim data set. In such cases, the encoded output includes the user data input, the first parity set, and the second parity set.

Other embodiments of the present invention provide hard disk storage devices that include: a storage medium; a read/write head assembly disposed in relation to the storage medium and operable to write an encoded output to the storage medium; and a rank independent data encoding circuit operable to: receive a user data input; and apply a rank independent encoding algorithm to the user data input to yield the encoded output. The rank independent encoding algorithm includes multiplying an interim data set with a quasi-pseudo inverse matrix

Yet other embodiments of the present invention provide methods for data encoding that include: receiving a user data set; and applying a rank independent encoding algorithm by an encoding circuit to the user data input to yield an encoded output. The rank independent encoding algorithm includes multiplying an interim data set by a quasi-pseudo inverse matrix. In some instances of the aforementioned embodiments, multiplying the interim data set by the quasi-pseudo inverse matrix is done by a sparse circulant vector multiplier circuit.

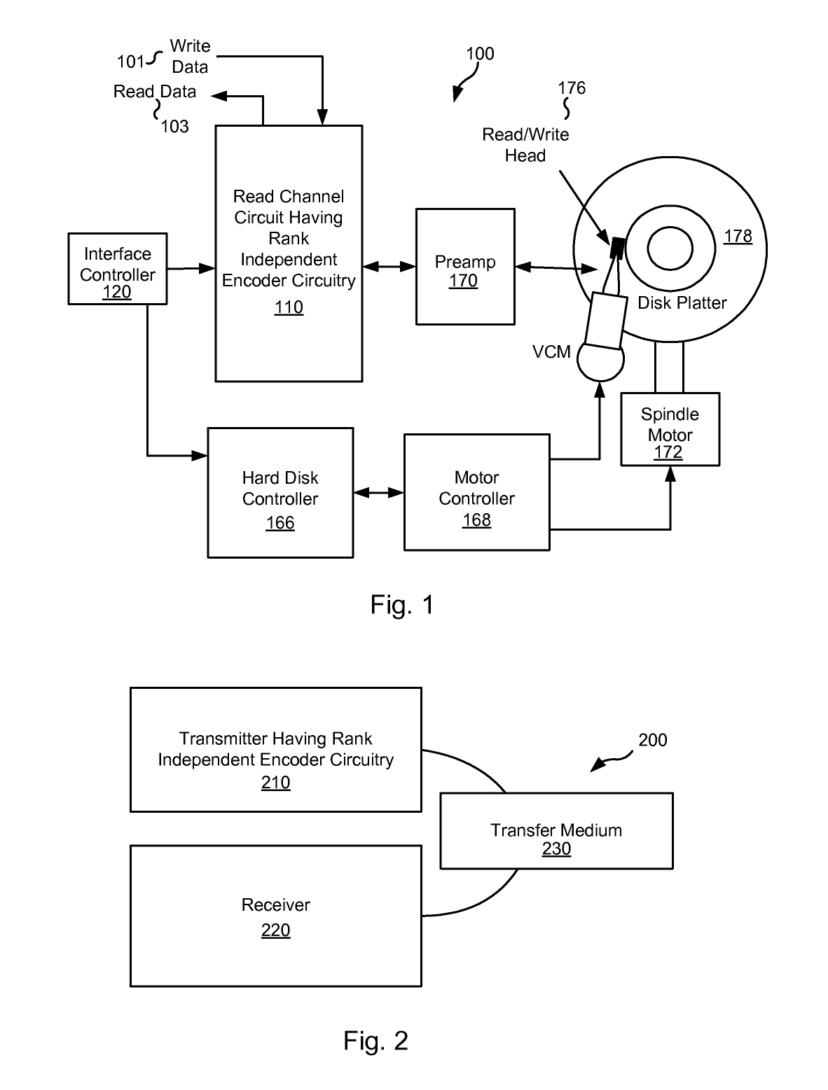

Turning to FIG. 1, a storage system 100 is shown that includes a read channel 110 having rank independent encoder circuitry in accordance with one or more embodiments of the present invention. Storage system 100 may be, for example, a hard disk drive. Storage system 100 also includes a preamplifier 170, an interface controller 120, a hard disk controller 166, a motor controller 168, a spindle motor 172, a disk platter 178, and a read/write head 176. Interface controller 120 controls addressing and timing of data to/from disk platter 178, and interacts with a host controller (not shown). The data on disk platter 178 consists of groups of magnetic signals that may be detected by read/write head assembly 176 when the assembly is properly positioned over disk platter 178. In one embodiment, disk platter 178 includes magnetic signals recorded in accordance with either a longitudinal or a perpendicular recording scheme.

In a typical read operation, read/write head 176 is accurately positioned by motor controller 168 over a desired data track on disk platter 178. Motor controller 168 both positions read/write head 176 in relation to disk platter 178 and drives spindle motor 172 by moving read/write head assembly 176 to the proper data track on disk platter 178 under the direction of hard disk controller 166. Spindle motor 172 spins disk platter 178 at a determined spin rate (RPMs). Once read/write head 176 is positioned adjacent the proper data track, magnetic signals representing data on disk platter 178 are sensed by read/write head 176 as disk platter 178 is rotated by spindle motor 172. The sensed magnetic signals are provided as a continuous, minute analog signal representative of the magnetic data on disk platter 178. This minute analog signal is transferred from read/write head 176 to read channel circuit 110 via preamplifier 170. Preamplifier 170 is operable to amplify the minute analog signals accessed from disk platter 178. In turn, read channel circuit 110 decodes and digitizes the received analog signal to recreate the information originally written to disk platter 178. This data is provided as read data 103 to a receiving circuit. A write operation is substantially the opposite of the preceding read operation with write data 101 being provided to read channel circuit 110. This data is then encoded and written to disk platter 178.

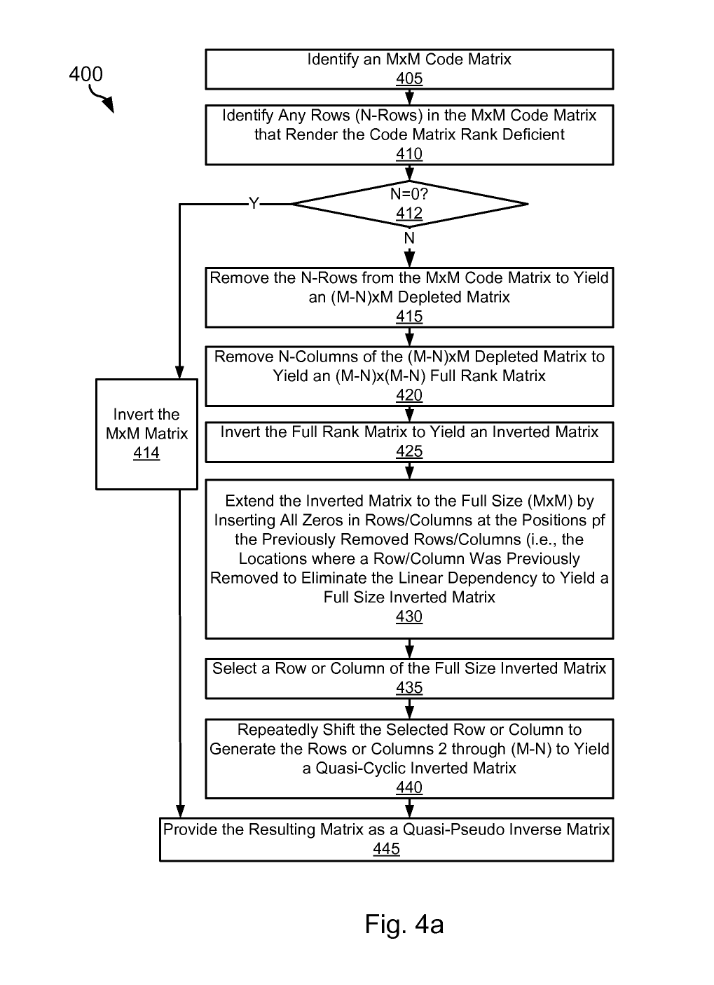

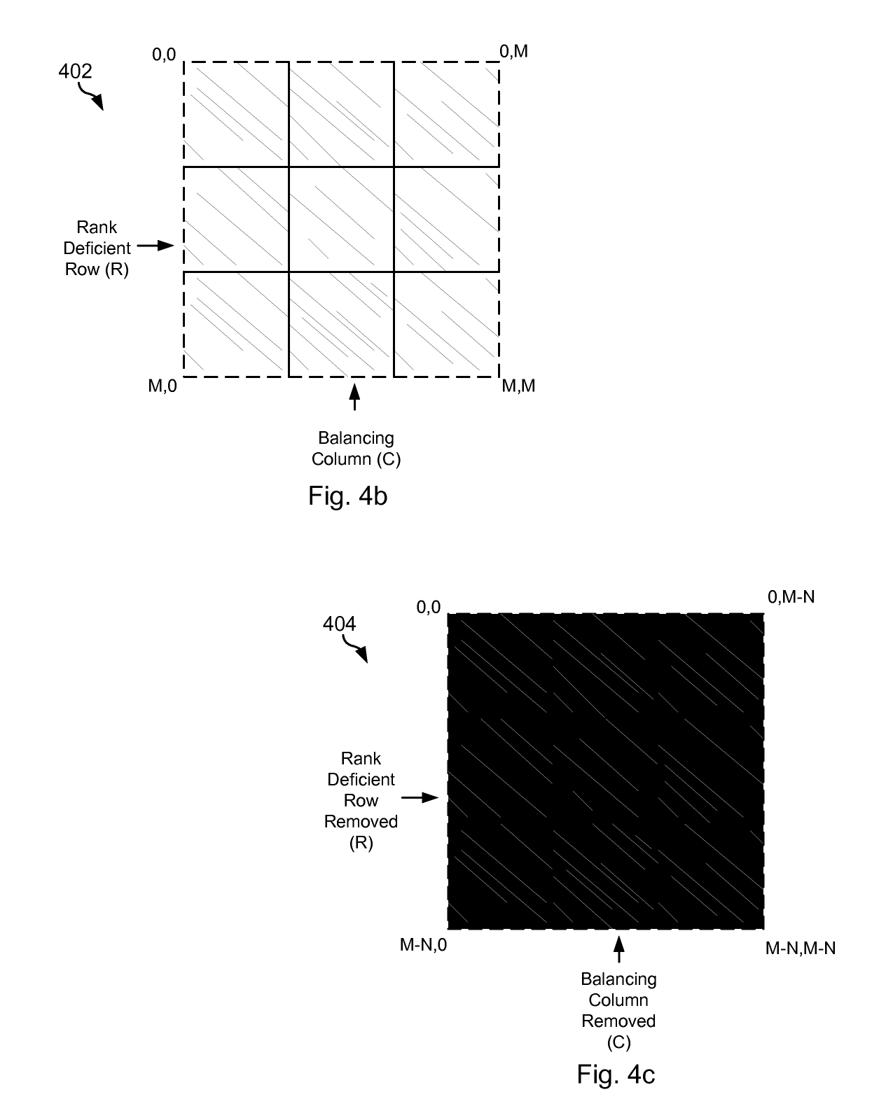

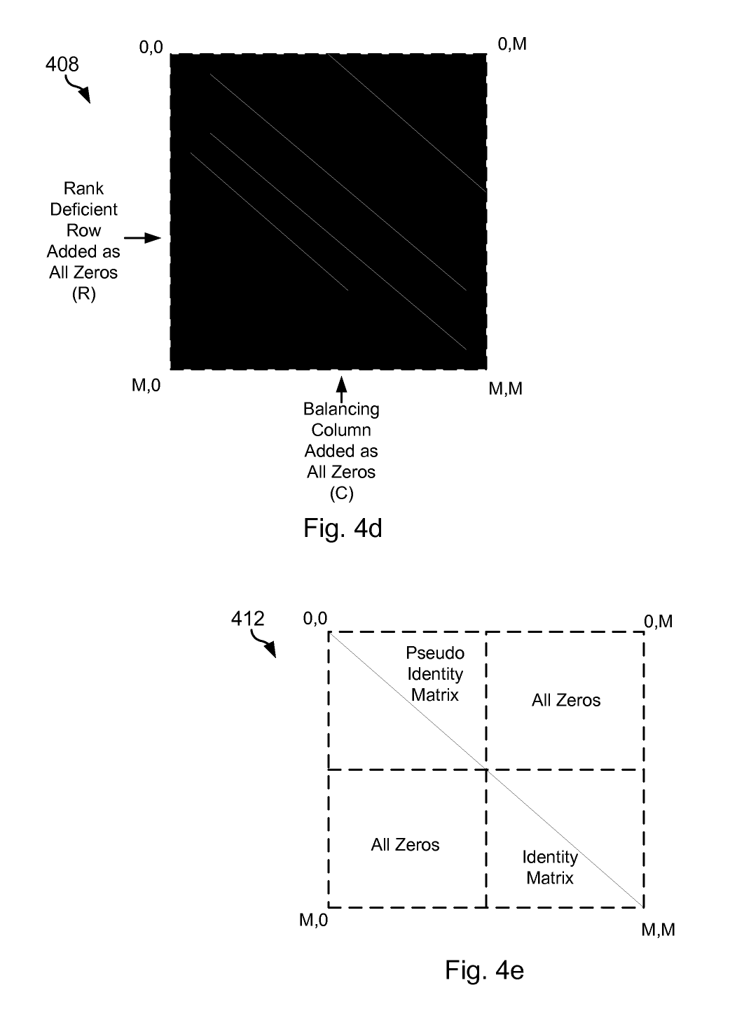

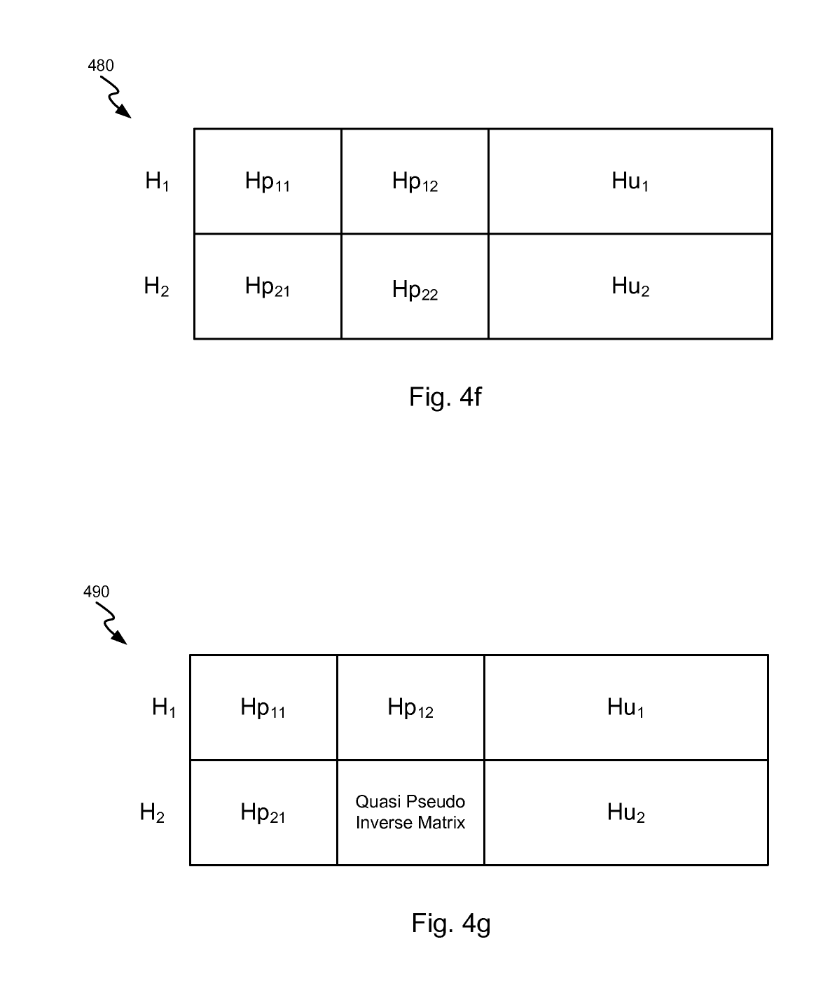

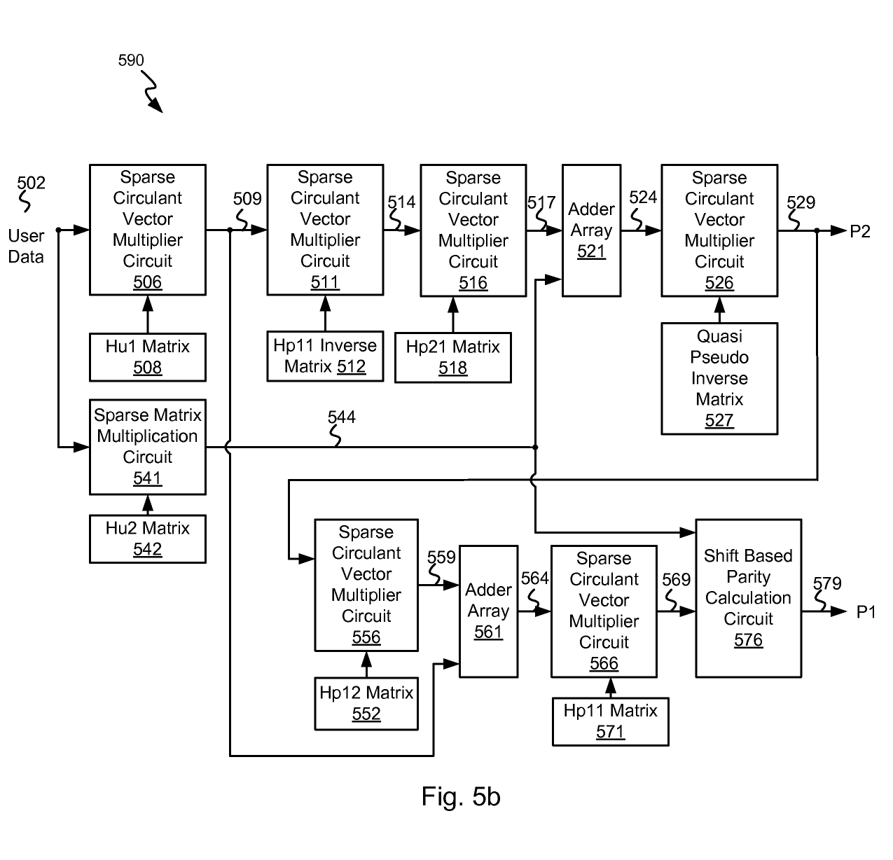

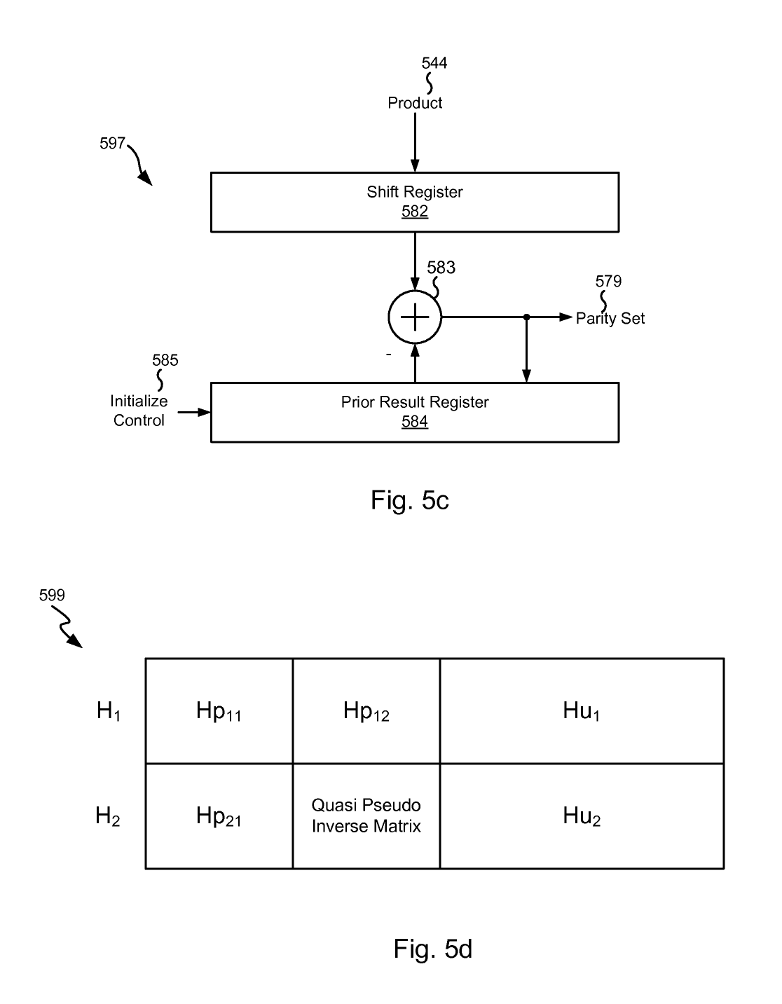

In operation, data stored to disk platter 178 is encoded using a rank independent encoder circuit to yield an encoded data set. Such a rank independent encoder circuit does not require a dense circulant multiplier circuit as rank deficient elements of the codeword are converted to a quasi-pseudo inverse matrix. This conversion may be done consistent with the approach discussed below in relation to FIGS. 4a-4e. One implementation of a rank independent encoder circuit that may be used in accordance with various embodiments of the present invention is discussed below in relation to FIGS. 5a-5d.

It should be noted that storage system 100 may be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such as storage system 100, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

A data decoder circuit used in relation to read channel circuit 110 may be, but is not limited to, a low density parity check (LDPC) decoder circuit as are known in the art. Such low density parity check technology is applicable to transmission of information over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as DRAM, NAND flash, NOR flash, other non-volatile memories and solid state drives.

In addition, it should be noted that storage system 100 may be modified to include solid state memory that is used to store data in addition to the storage offered by disk platter 178. This solid state memory may be used in parallel to disk platter 178 to provide additional storage. In such a case, the solid state memory receives and provides information directly to read channel circuit 110. Alternatively, the solid state memory may be used as a cache where it offers faster access time than that offered by disk platted 178. In such a case, the solid state memory may be disposed between interface controller 120 and read channel circuit 110 where it operates as a pass through to disk platter 178 when requested data is not available in the solid state memory or when the solid state memory does not have sufficient storage to hold a newly written data set. Based upon the disclosure provided herein, one of ordinary skill in the art will recognize a variety of storage systems including both disk platter 178 and a solid state memory.

Turning to FIG. 2, a data transmission system 200 including a transmitter 210 having rank independent encoder circuitry in accordance with one or more embodiments of the present invention. Transmitter 210 transmits encoded data via a transfer medium 230. Transfer medium 230 may be a wired or wireless transfer medium. Based upon the disclosure provided herein, one of ordinary skill in the art will recognize a variety of transfer mediums that may be used in relation to different embodiments of the present invention. The encoded data is received from transfer medium 230 by receiver 220. In operation, transmitter 210 encodes user data using a rank independent encoder circuit to yield an encoded data set. Such a rank independent encoder circuit does not require a dense circulant multiplier circuit as rank deficient elements of the codeword are converted to a quasi-pseudo inverse matrix. This conversion may be done consistent with the approach discussed below in relation to FIGS. 4a-4e. One implementation of a rank independent encoder circuit that may be used in accordance with various embodiments of the present invention is discussed below in relation to FIGS. 5a-5d.

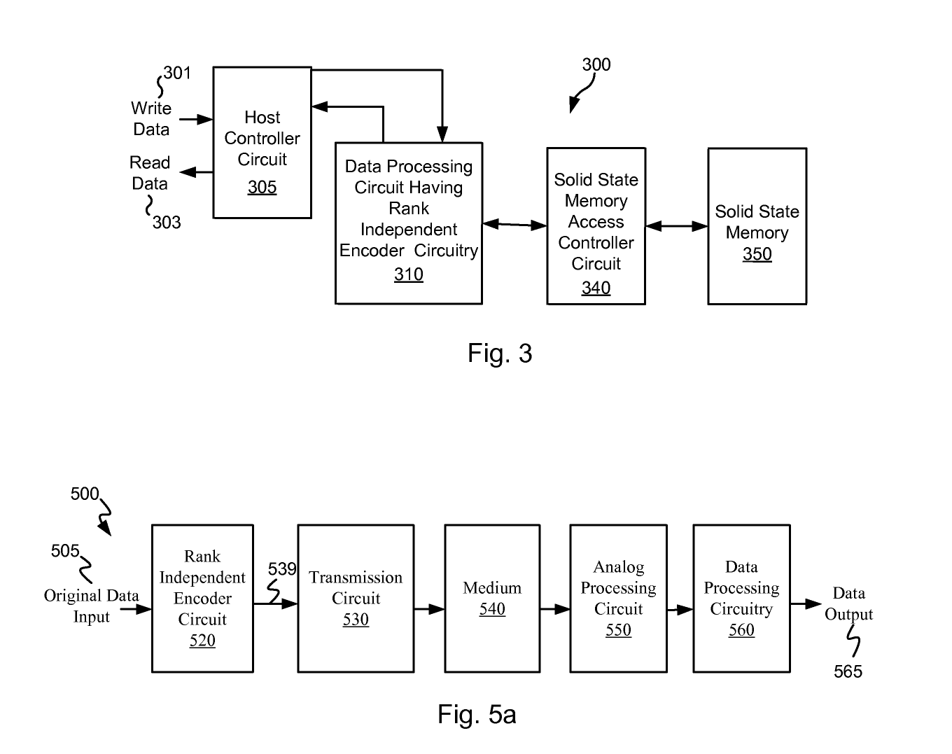

Turning to FIG. 3, another storage system 300 is shown that includes a data processing circuit 310 having rank independent encoder circuitry in accordance with one or more embodiments of the present invention. A host controller circuit 305 receives data to be stored (i.e., write data 301). Solid state memory access controller circuit 340 may be any circuit known in the art that is capable of controlling access to and from a solid state memory 350. Solid state memory access controller circuit 340 encodes a received data set to yield an encoded data set. The encoding is done using a rank deficient LDPC encoder circuit, and results in an encoded data set that is stored to solid state memory 350. Solid state memory 350 may be any solid state memory known in the art. In some embodiments of the present invention, solid state memory 350 is a flash memory. In operation, data processing circuit 310 encodes user data using a rank independent encoder circuit to yield an encoded data set. Such a rank independent encoder circuit does not require a dense circulant multiplier circuit as rank deficient elements of the codeword are converted to a quasi-pseudo inverse matrix. This conversion may be done consistent with the approach discussed below in relation to FIGS. 4a-4e. One implementation of a rank independent encoder circuit that may be used in accordance with various embodiments of the present invention is discussed below in relation to FIGS. 5a-5c.

Turning to FIG. 4a, a flow diagram 400 shows a method for generating a quasi-pseudo inverse matrix that may be used for rank independent encoding in accordance with various embodiments of the present invention. As used herein, the phrase “quasi-pseudo inverse matrix” is used in its broadest sense to mean any original matrix that is simplified to have quasi-cyclic structure that when multiplied by the original matrix yields a sparse matrix with regular structure. Following flow diagram 400, an M×M code matrix is identified (block 405). The M×M code matrix may be either a full rank matrix or a rank deficient matrix. A rank deficient matrix includes one or more columns or rows that is linearly dependent upon one or more other columns or rows. For example, where one or more columns is linearly dependent upon one or more other columns in the M×M code matrix, the M×M code matrix is a rank deficient matrix. As another example, where one or more rows is linearly dependent upon one or more other rows in the M×M code matrix, the M×M code matrix is similarly a rank deficient matrix. In a full rank matrix, all rows and columns are linearly independent of each other. In some embodiments of the present invention, referring to FIG. 4f, the M×M code matrix is an Hp22 matrix shown as part of an overall code matrix 480 as is commonly used in the art. Of note, in some cases, such an Hp22 matrix is denoted as an H̅p₂₂ (similarly, Hp21 matrix may be denoted H̅p₂₁, and Hu2 matrix may be denoted H̅u₂), but for the purposes of this document the notation should imply a matrix either with or without the bar. FIG. 4b shows an example of an M×M code matrix 402 including one row rendering the M×M code matrix rank deficient (rank deficient row (R)), and one column selected for removal to balance the rank deficient row (balancing column (C)). The diagonal lines indicate locations of non-zero elements, and the white areas indicate the location of zero elements.

The M×M code matrix is queried to determine whether one or more rows in the matrix are linearly dependent upon any other row(s) in the matrix (block 410). It should be noted that in alternative embodiments it could be determined whether one or more columns in the matrix are linearly dependent upon any other column(s) in the matrix. The location of the identified linearly dependent rows is maintained, and the number of the identified linearly dependent rows is N.

It is determined whether and linear dependencies have been identified (i.e., whether N=0) (block 412). Where no linearly dependent rows are identified (block 412), the M×M code matrix is inverted (block 414), and the inverted matrix is provided as an M×M quasi-pseudo inverse matrix (block 455). Alternatively, where it is determined that there are one or more linearly dependent rows (i.e., N>0) (block 412), the identified rows are removed from the M×M code matrix to yield an (M-N)×M depleted matrix (block 415). A corresponding number of columns are also removed from the (M-N)×M depleted matrix to yield an (M-N)×(M-N) full rank matrix (block 420). The removed rows/columns are generally referred to herein as removed rows/columns. As all of the linearly dependent rows have been removed, the remaining matrix is a full rank matrix.

The aforementioned (M-N)×(M-N) full rank matrix is then inverted to yield an inverted matrix (block 425). Inversion includes changing all ones in the matrix to zeros, and all zeros in the matrix to ones. FIG. 4c shows an example of an inverted (M-N)×(M-N) full rank matrix 404. The diagonal white lines indicate locations of zero elements, and the black areas indicate the location of non-zero elements.

The inverted matrix is then extended back to its full size (M×M) by inserting rows of all zeros at locations of the previously removed rows, and columns of all zeros at locations of the previously removed columns (block 430). This process yields a full size inverted matrix. One row or column of the full size inverted matrix is selected (block 430), and the selected row or column is repeatedly shifted to generate a quasi-cyclic inverted matrix (block 435). As an example, the first row of the inverted matrix is selected and repeatedly shifted for each of rows 2 through (M-N) to yield the quasi-cyclic inverted matrix (block 440). The result is provided as an M×M quasi-pseudo inverse matrix (block 455). FIG. 4d shows an example of an M×M quasi-pseudo inverse matrix where the white lines indicate locations of zeros, and the black indicate locations of ones.

The resulting M×M quasi-pseudo inverse matrix may be multiplied by the original M×M code matrix resulting in a product having a regular structure that is easily modulated onto a desired vector. FIG. 4e shows an example product 412 of the multiplication of the M×M code matrix by the M×M quasi-pseudo inverse matrix where the locations of non-zero elements correspond to the diagonal line, and other locations are zero. As shown, example product 412 includes two quadrants that are all zeros, an upper left quadrant that is a pseudo identity matrix, and a lower right quadrant that is an identity matrix. Following the example of FIG. 4f and referring to FIG. 4g, an overall encoding matrix 490 is shown with the Hp22 matrix replaced by the quasi-pseudo inverse matrix.

Turning to FIG. 5a, shows a processing system 500 including a rank independent encoder circuit 520 in accordance with some embodiments of the present invention. Data processing system 500 includes rank independent encoder circuit 520 that applies a rank independent encoding algorithm to an original data input 505 to yield an encoded output 539. Application of the rank independent encoding algorithm includes performing a number of vector multiplications by quasi-cyclic matrices. One of the quasi-cyclic matrices is the quasi-pseudo inverse matrix described above in relation to FIGS. 4a-4e. By performing the vector multiplications on quasi-cyclic matrices instead of dense matrices as is generally performed where a rank deficient matrix is involved, increased throughput and reduced circuit area are achievable. Further, by utilizing the quasi-pseudo inverse matrix described above in relation to FIGS. 4a-4e in place of either another on quasi-cyclic vector multiplier used for full rank matrices or a dense circulant vector multiplier used for rank deficient matrices, processing system 500 provides similar results for both rank deficient and full rank codewords. By using cyclic codes, the read only memories included to perform the encoding may be size reduced and include only a single row or column of the particular matrix, and the other rows or columns can be regenerated using a cyclic shift of the stored pattern. As the quasi-pseudo inverse matrix is not an identity matrix, a post processing circuit is added to calculate parity data generated based upon the multiplication by the quasi-pseudo inverse matrix.

Encoded output 539 is provided to a transmission circuit 530 that is operable to transmit the encoded data to a recipient via a medium 540. Transmission circuit 530 may be any circuit known in the art that is capable of transferring encoded output 539 via medium 540. Thus, for example, where data processing circuit 500 is part of a hard disk drive, transmission circuit 530 may include a read/write head assembly that converts an electrical signal into a series of magnetic signals appropriate for writing to a storage medium. Alternatively, where data processing circuit 500 is part of a wireless communication system, transmission circuit 530 may include a wireless transmitter that converts an electrical signal into a radio frequency signal appropriate for transmission via a wireless transmission medium. Transmission circuit 530 provides a transmission output to medium 540. Medium 540 provides a transmitted input that is the transmission output augmented with one or more errors introduced by the transference across medium 540.

Of note, original data input 505 may be any data set that is to be transmitted. For example, where data processing system 500 is a hard disk drive, original data input 505 may be a data set that is destined for storage on a storage medium. In such cases, a medium 540 of data processing system 500 is a storage medium. As another example, where data processing system 500 is a communication system, original data input 505 may be a data set that is destined to be transferred to a receiver via a transfer medium. Such transfer mediums may be, but are not limited to, wired or wireless transfer mediums. In such cases, a medium 540 of data processing system 500 is a transfer medium.

Data processing circuit 500 includes an analog processing circuit 550 that applies one or more analog functions to the transmitted input. Such analog functions may include, but are not limited to, amplification and filtering. Based upon the disclosure provided herein, one of ordinary skill in the art will recognize a variety of pre-processing circuitry that may be used in relation to different embodiments of the present invention. In addition, analog processing circuit 550 converts the processed signal into a series of corresponding digital samples. Data processing circuitry 560 applies data detection and/or data decoding algorithms to the series of digital samples to yield a data output 565. Based upon the disclosure provided herein, one of ordinary skill in the art will recognize a variety of data processing circuitry that may be used to recover original data input from the series of digital samples.

Turning to FIG. 5b, one implementation of rank independent encoder circuit 520 of FIG. 5a is shown as an encoding circuit 590 in accordance with one or more embodiments of the present invention. Encoding circuit 590 utilizes an encoding matrix 599 as shown in FIG. 5d. Encoding circuit 590 includes a sparse circulant vector multiplication circuit 505 that multiplies a user data input 502 (u) by a portion of an encoding matrix, Hu₁ matrix 507 (Hu₁), to yield a product 509 in accordance with the following equation:

Product 509=u×Hu₁.

Hu₁ matrix 507 (Hu₁) may be maintained in a read only memory.

In addition, encoding circuit 500 includes a sparse circulant vector multiplication circuit 541 that multiplies a user data input 502 (u) by a portion of an encoding matrix, Hu₂ matrix 542 (Hu₂), to yield a product 544 in accordance with the following equation:

Product 544=u×Hu₂.

Hu₂ matrix 542 (Hu₂) may be maintained in a read only memory.

Another sparse circulant vector multiplication circuit 511 multiplies product 509 by an inverse portion of the encoding matrix, Hp₁₁ matrix 512 (Hp₁₁), to yield a product 514 in accordance with the following equation:

Product 514=[u×Hu₁]×Hp₁₁.

Hp₁₁ matrix 512 (Hp₁₁) may be maintained in a read only memory.

Another sparse circulant vector multiplication circuit 516 multiplies product 514 by an the encoding matrix, Hp₂₁ matrix 518 (Hp₂₁), to yield a product 517 in accordance with the following equation:

Product 517=[[u×Hu₁]×Hp₁₁⁻¹]×Hp₂₁.

Hp₂₁ matrix 518 (Hp₂₁) may be maintained in a read only memory.

Product 517 and Product 544 are provided to a Galois field adder array 521 where a vector addition is performed in accordance with the following equation to yield a sum 524:

Sum 524=[[[u×Hu₁]×Hp₁₁⁻¹]×Hp₂₁]+[u×Hu₂].

Sum 524 is provided to another sparse circulant vector multiplication circuit 526 that multiplies sum 524 by a quasi-pseudo inverse matrix 527 to yield a parity set 529 (p₂) in accordance with the following equation:

Parity Set 529=Sum 524×Quasi−Pseudo Inverse Matrix 529.

Quasi-pseudo inverse matrix 527 is a matrix generated using the process described above in relation to FIGS. 4a-4e. As quasi-pseudo inverse matrix 527 exhibits a quasi-cyclic structure, read only memory storing quasi-pseudo inverse matrix 527 is only required to store one row of the structure and the multiplication performed by sparse circulant vector multiplication circuit 526 operates on a repeatedly shifted version of the stored row. Further, due to the regularity of quasi-pseudo inverse matrix 527, sparse circulant vector multiplication circuit 526 may be substantially less complex than a corresponding dense multiplier circuit traditionally used for encoding using rank deficient matrices. Said another way, embodiments of the present invention provide an ability to encode data sets using rank deficient matrices using less complex hardware that requires less die area and power.

Parity set 529 is provided to another sparse circulant vector multiplication circuit 556 that multiplies parity set 529 by an the encoding matrix, Hp₁₂ matrix 552 (Hp₁₂), to yield a product 559 in accordance with the following equation:

Product 559=Parity Set 529×Hp₁₂.

Hp₁₂ matrix 552 (Hp₁₂) may be maintained in a read only memory. Product 559 and Product 509 are provided to a Galois field adder array 561 where a vector addition is performed in accordance with the following equation to yield a sum 564:

Sum 564=Product 559+Product 509.

Sum 564 is provided to another sparse circulant vector multiplication circuit 566 that multiplies sum 564 by an inverse portion of the encoding matrix, Hp₁₁ matrix 571 (Hp₁₁), to yield a product 569 in accordance with the following equation:

Product 569=Sum 564×Hp₁₁.

Hp₁₁ matrix 571 (Hp₁₁) may be maintained in a read only memory.

Product 544 and product 569 are provided to a shift based parity calculation circuit 576. Shift based parity calculation circuit 576 operates to resolve a series of linear equations to yield a parity set 579 (p₁). The series of linear equations are as follow:

$$Parity Set 579 ( 1 ) + Parity Set 579 ( n ) = Product 544 ( 1 ) ;$$

$$Parity Set 579 ( 1 ) + Parity Set 579 ( 2 ) = Product 544 ( 2 ) ;$$

$$Parity Set 579 ( 2 ) + Parity Set 579 ( 3 ) = Product 544 ( 3 ) ;$$

$$Parity Set 579 ( 3 ) + Parity Set 579 ( 4 ) = Product 544 ( 4 ) ;$$

$$… ;$$

$$Parity Set 579 ( n - 1 ) + Parity Set 579 ( n ) = Product 544 ( n ) .$$

The values of Product 544(1 . . . n) are established and therefore known due to their prior calculation by sparse circulant vector multiplication circuit 541. Further the value of parity set 579(n) is set to zero. As such, the value for parity set 579(1) can be solved using the equation:

Parity Set 579(1)+Parity Set 579(n)=Product 544(1).

Once the value of parity set 579(1) is known, the value for parity set 579(2) can be solved using the equation:

Parity Set 579(1)+Parity Set 579(2)=Product 544(2).

This process of solving for each of the values of parity set 579 is sequentially performed. Finally, the combination of user data 502, parity set 529, and parity set 579 are provided as an encoded data set.

Turning to FIG. 5c, one implementation of a shift based parity calculation circuit 597 in accordance with one or more embodiments of the present invention. Shift based parity calculation circuit 597 may be used in place of shift based parity calculation circuit 576 of FIG. 5b. Shift based parity calculation circuit 597 includes a prior result register 584 that is initialized to zero at the beginning of solving the aforementioned series of equations as indicated by assertion of an initialize control signal 585. A summation circuit 583 subtracts a prior result (i.e., parity set 579(i-1)) from a corresponding element of product 544 (i.e., product 544(i)) as provided by a shift register 582. The result from summation circuit 583 is provided as part of parity set 579 (i.e., parity set 579(i)). The recently calculated element of parity set 579 is stored back to prior result register 584 where it is used in relation to the next shifted element of product 544 to yield the next element of parity set 579.

It should be noted that the various blocks discussed in the above application may be implemented in integrated circuits along with other functionality. Such integrated circuits may include all of the functions of a given block, system or circuit, or a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the invention provides novel systems, devices, methods and arrangements for data processing. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims

What is claimed is:

1. A data processing system, the data processing system comprising:
a rank independent data encoding circuit operable to:
receive a user data input; and
apply a rank independent encoding algorithm to the user data input to yield an encoded output, wherein the rank independent encoding algorithm includes multiplying an interim data set by a quasi-pseudo inverse matrix.

2. The data processing system of claim 1, wherein the quasi-pseudo inverse matrix is part of an encoding matrix, and wherein the encoding matrix further includes a first user matrix, a second user matrix, a first interim matrix, a second interim matrix.

3. The data processing system of claim 2, wherein the interim data set is a first interim data set, and wherein the rank independent data encoding circuit comprises:
a first vector multiplier circuit operable to multiply the user data input by an inverse of the first user matrix to yield a second interim data set;
a second vector multiplier circuit operable to multiply the second interim data set by the first interim matrix to yield a third interim data set;
a third vector multiplier circuit operable to multiply the third interim data set by the second interim matrix to yield a fourth interim data set;
a fourth vector multiplier circuit operable to multiply the user data input by the second user matrix to yield a fifth interim data set; and
a fifth vector multiplier circuit operable to multiply a combination of the fourth interim data set and the fifth interim data set by the quasi-pseudo inverse matrix to yield the first interim data set.

4. The data processing system of claim 3, wherein the rank independent data encoding circuit further comprises:
an adder array circuit operable to add the fourth interim data set to the fifth interim data set to yield the combination of the fourth interim data set and the fifth interim data set.

5. The data processing system of claim 4, wherein the encoding matrix further includes a third interim matrix.

6. The data processing system of claim 5, wherein the rank independent data encoding circuit further comprises:
a sixth vector multiplier circuit operable to multiply the first interim data set by the third interim matrix to yield a sixth interim data set; and
a seventh vector multiplier circuit operable to multiply a combination of the fifth interim data set and the sixth interim data set by the first user matrix to yield a seventh interim data set.

7. The data processing system of claim 6, wherein each of the sixth vector multiplier circuit and the seventh vector multiplier circuit is a sparse circulant vector multiplier circuit.

8. The data processing system of claim 6, wherein the adder array circuit is a first adder array circuit, and wherein the rank independent data encoding circuit further comprises:
a second adder array circuit operable to add the fifth interim data set to the sixth interim data set to yield the combination of the fifth interim data set and the sixth interim data set.

9. The data processing system of claim 6, wherein the first interim data set is a first parity set, and wherein the rank independent data encoding circuit further comprises:
a shift based parity calculation circuit operable to calculate a second parity set based at least in part on the seventh interim data set, and wherein the encoded output includes the user data input, the first parity set, and the second parity set.

10. The data processing system of claim 3, wherein each of the first vector multiplier circuit, the second vector multiplier circuit, the third vector multiplier circuit, the fourth vector multiplier circuit, and the fifth vector multiplier circuit is a sparse circulant vector multiplier circuit.

11. The data processing system of claim 1, wherein the quasi-pseudo inverse matrix represents a rank deficient matrix.

12. The data processing system of claim 1, wherein the quasi-pseudo inverse matrix represents a full rank matrix.

13. The data processing system of claim 1, wherein the system is implemented as part of an integrated circuit.

14. The data processing system of claim 1, wherein the system is implemented as part of an electronic device selected from a group consisting of: a storage drive, and a communication device.

15. A method for data encoding, the method comprising:
receiving a user data set;
applying a rank independent encoding algorithm by an encoding circuit to the user data input to yield an encoded output, wherein the rank independent encoding algorithm includes multiplying an interim data set by a quasi-pseudo inverse matrix.

16. The method of claim 15, multiplying the interim data set by the quasi-psuedo inverse matrix is done by a sparse circulant vector multiplier circuit.

17. The method of claim 15, wherein the interim data set is a first interim data set, wherein the quasi-pseudo inverse matrix is part of an encoding matrix, wherein the encoding matrix further includes a first user matrix, a second user matrix, a first interim matrix, a second interim matrix, and wherein the method further comprises:
multiplying the user data input by an inverse of the first user matrix to yield a second interim data set;
multiplying the second interim data set by the first interim matrix to yield a third interim data set;
multiplying the third interim data set by the second interim matrix to yield a fourth interim data set;
multiplying the user data input by the second user matrix to yield a fifth interim data set;
adding the fourth interim data set to the fifth interim data set to yield a combination of the fourth interim data set and the fifth interim data set; and
multiplying the combination of the fourth interim data set and the fifth interim data set by the quasi-pseudo inverse matrix to yield the first interim data set.

18. The method of claim 17, wherein the encoding matrix further includes a third interim matrix, the method further comprising:
multiplying the first interim data set by the third interim matrix to yield a sixth interim data set; and
adding the fifth interim data set to the sixth interim data set to yield a combination of the fifth interim data set and the sixth interim data set; and
multiplying the combination of the fifth interim data set and the sixth interim data set by the first user matrix to yield a seventh interim data set.

19. The method of claim 18, wherein the first interim data set is a first parity set, the method further comprising:
applying a shift based parity calculation to calculate a second parity set based at least in part on the seventh interim data set, and wherein the encoded output includes the user data input, the first parity set, and the second parity set.

20. A hard disk storage device, the device comprising:
a storage medium;
a read/write head assembly disposed in relation to the storage medium and operable to write an encoded output to the storage medium; and
a rank independent data encoding circuit operable to:
receive a user data input; and
apply a rank independent encoding algorithm to the user data input to yield the encoded output, wherein the rank independent encoding algorithm includes multiplying an interim data set by a quasi-pseudo inverse matrix.
